(19) United States
(12) Patent Application Publication
(10) Pub. No.: US 2002/0009001 A1
(43) Pub. Date: Jan. 24, 2002

(54) Integrated circuit with a matrix of programmable logic cells

(76) Inventors: Jean-Paul Theis, Erpeldange (LU); Katarzyna Leijten-Nowak, Eindhoven (NL); Jozef Louis Van Meerbergen, Eindhoven (NL)

Correspondence Address: U.S. Philips Corporation, Intellectual Property Department, 580 White Plains Road, Tarrytown, NY, 10591, US

(21) Appl. No.: 09/867,894

(22) Filed: May 30, 2001

(30) Foreign Application Priority Data
May 30, 2000 (EP) 00201910.7

(51) Int. Cl. G11C 29/00

(52) U.S. Cl. 365/200

(57) ABSTRACT

An integrated circuit has a matrix of programmable cells. Programmable switches connect pairs of neighboring cells. Each cell contains a local conductor connecting a pair of the switches on opposite sides of the cell. Each switch connects the local conductors of the neighboring cells. At least one of the cells have a computation logic circuit having either an input connected to the local conductor of the at least one of the cells. The computation logic circuit has programmably individually activatable outputs connected to the local conductors of neighbor cells of the at least one of the cells or an output connected to the local conductor of the at least one of the cells and programmably individually activatable inputs connected to the local conductors of neighbor cells of the at least one of the cells.

The invention relates to an integrated circuit with programmable logic with an interconnected matrix of programmable logic cells.

From U.S. Pat. No. 6,014,509 it is known to arrange programmable logic cells in a matrix. Each cell has a programmable computation function. The result of the computation can be passed to other cells where it may be used as input for further computations. This allows the implementation of complex computational functions. The efficiency of such computations, in terms of integrated circuit substrate area that is required to implement the function, depends, amongst others, on the flexibility with which results can be routed between cells. The circuit of U.S. Pat. No. 6,014,509 provides for routing of a result of one cell to all of its neighbors and to busses that are shared by cells in rows and columns of the matrix respectively. Cells are programmed to select their inputs from their neighbors and/or the busses.

Amongst others, it is an object of the invention to improve the efficiency with which functions can be implemented in an integrated circuit with a matrix of computing cells.

The integrated circuit according to the invention is described in claim 1. According to the invention, programmable switches are located between adjacent cells and the cells contain local conductors that connect the switches on opposite sides of the cells. The switches connect conductors of neighboring cells. In a matrix of rows and columns for example, local conductors connect the switches on opposite sides in the row direction and other local conductors connect the switches on opposite sides in the column direction. A cell also contains a computation logic circuit, which preferably is programmable, with an input and outputs. The input is connected to the conductor of the cell and the outputs are programmably connected to the conductors of neighboring cells. Whether an output is actively connected to the conductor of a neighboring cell can be programmed individually for different neighboring cells.

Thus, the cell provides both for computation and for routing data from and between neighboring cells. To keep the conductors of the cell free for receiving input signals, the output of the computation logic circuit of a cell is connected to the conductors of the neighboring cells, from where the output can be isolated from the conductor of the cell by means of the switches between the cells. It can be selected which of the neighboring cells receive the output and which do not receive the output. The conductors of the latter can be connected to the cell by the switches for supplying an input routed through the neighboring cell, but of course the input may also be received directly from the output of the neighboring cell, because this output is in turn connected to the conductor of the cell. In an alternative embodiment, the connections of inputs and outputs are interchanged, the output being coupled to the conductor of the cell and the inputs being individually programmably connected to the conductors of the neighboring cells.

In an embodiment the cell contains a plurality of local conductors that connect switches on opposite sides of the cell. Each conductor is connected by the switch to a different corresponding connector in the neighboring cell. The computation logic circuit has inputs connected to the conductors of the cell. In a further embodiment, the cell contains a programmable interconnection switch for making a programmable connection between conductors in the cell. Thus, it is possible to provide more complicated routing, from one conductor to another, in the cell.

In another embodiment the matrix has rows and columns. Local row conductors connect the switches on opposite sides in the row direction and local column conductors connect the switches on opposite sides in the column direction. In a further embodiment, the cell contains cross connection switches between the local row conductors and the local column conductors. The combination of the switches between cells and cross-connection switches allows more complicated routing, where the cell serves to rout data from for example a neighboring cell in the column direction to a neighboring cell in the row direction.

In another embodiment of the integrated circuit according to the invention, the circuit also contains global conductors, which run through a number of cells in the same row or column for example. The computation logic circuit has inputs and outputs connected to the global conductors as well. This allows routing between cells at greater distances without encumbering the local conductors of the intervening cells.

These and other advantageous aspects of the integrated circuit according to the invention will be described using the following figures.

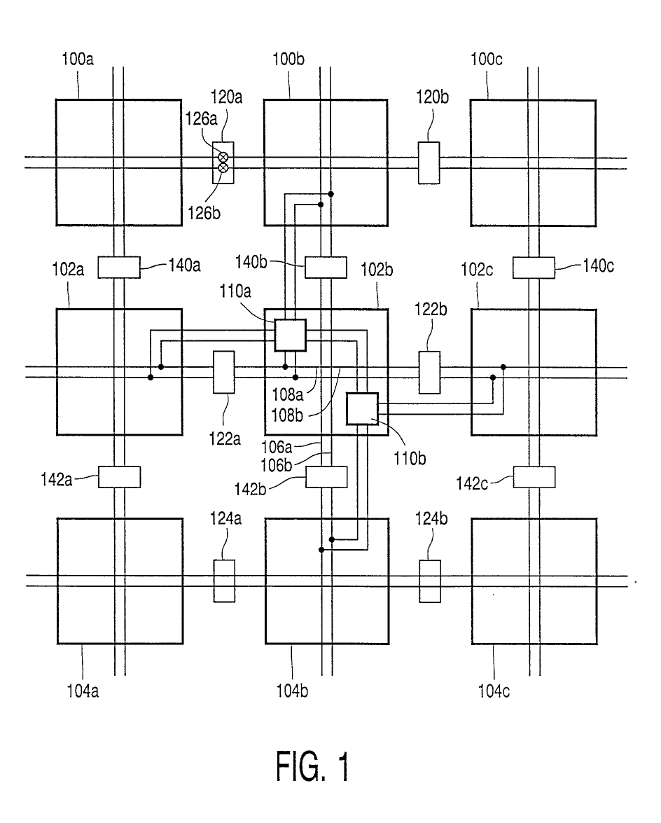

FIG. 1 shows a matrix of programmable cells

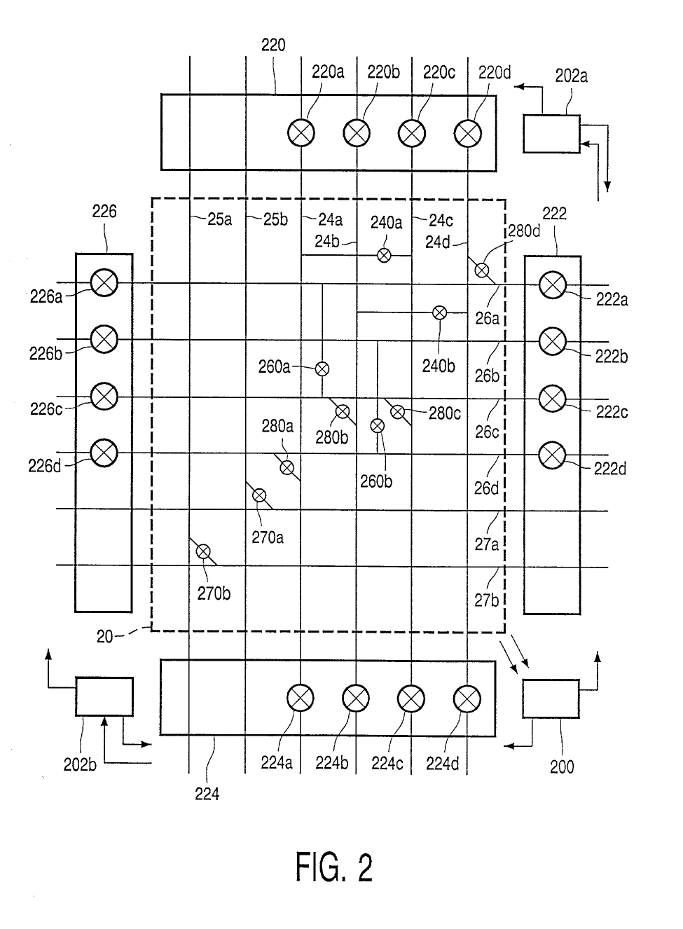

FIG. 2 shows a routing plane of a cell

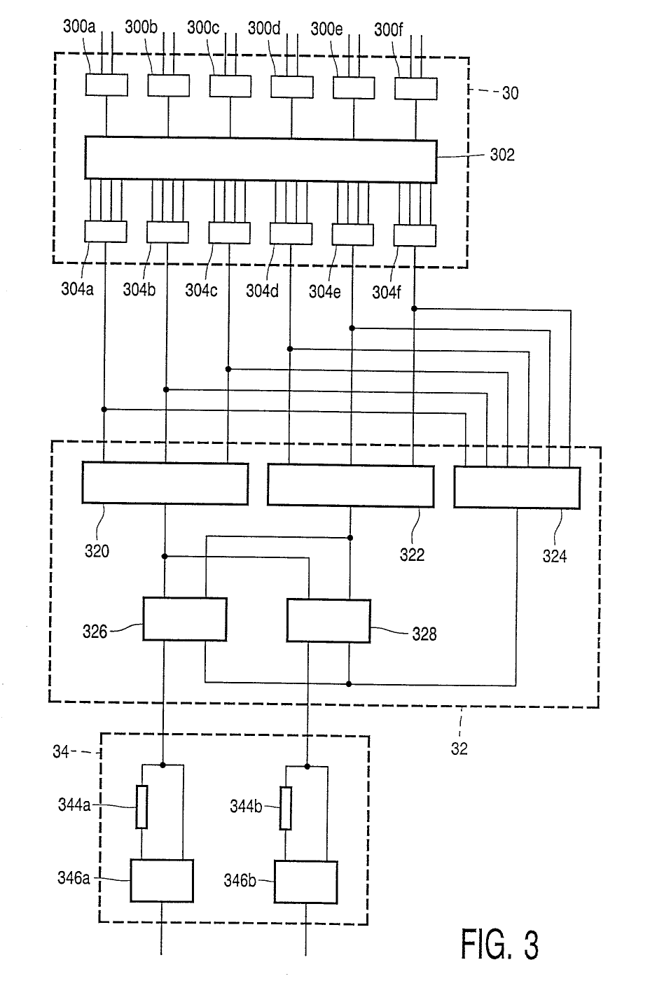

FIG. 3 shows a computation logic circuit.

FIG. 1 shows a matrix of programmable cells 100a-c, 102a-c, 104a-c, arranged in rows and columns. Between neighboring cells connection circuits 120a-c, 122a-c, 140a-c, 142a-c, 144a-c are shown. Two pairs of local conductors (e.g. 106a,b and 108a,b) are shown in each cell 100a-c, 102a-c, 104a-c, running in a row direction and in a column direction respectively. Each pair of local conductors 108a,b that runs in the row direction is coupled to the pairs of local conductors of the neighboring cells in the row direction via a connection circuit 120a-c, 122a-c in the row direction. Each pair of local conductors 106a,b that runs in the column direction is coupled to the pairs of local conductors of the neighboring cells in the column direction via a connection circuit 140a-c, 142a-c in the column direction. Each connection circuit contain switches 124a,b connecting the local conductors of the neighboring cells. The switches 124a,b of only one connection circuit 120a are shown explicitly for reasons of clarity.

Each cell 100a-c, 102a-c, 104a-c contains a programmable computation logic circuit 110a,b (the computation logic circuit 110a,b of only one of the cells 120a being shown explicitly for reasons of clarity. Moreover the computation logic circuit 110a,b is shown in two parts 110a,b in order to avoid encumbering the figure with connections. In reality, the computation logic circuit 110a,b may be a single part performing its function as a whole), with inputs connected to the local conductors of the cell. The computation logic circuit has an output coupled to conductors 106a,b, 108a,b of the neighboring cells 100a-c, 102a-c, 104a-c “behind” the connection circuit, i.e. with the connection circuit between the output and the local conductors 106a,b, 108a,b of the cell to which the inputs of the computation logic circuit are connected.

The open/closed state of the switches in the connection circuits 120a-c, 122a-c, 140a-c, 142a-c, 144a-c and the function of the computation logic circuit are controlled by configuration data in configuration memory locations (not shown).

In operation each computation logic circuits 120a-c, 122a-c, 140a-c, 142a-c, 144a-c receive data from the local conductors of the cells to which the computation logic circuit 120a-c, 122a-c, 140a-c, 142a-c, 144a-c belongs. From this data the computation logic circuit 120a-c, 122a-c, 140a-c, 142a-c, 144a-c computes result data. The result data is applied to the local conductors of selected ones of the neighboring cells, the selection being controlled by the configuration data.

The result data is used as input by the computation logic circuit of one or more other cells 120a-c, 122a-c, 140a-c, 142a-c, 144a-c. This can be the cells that neighbor the particular cell of the computation logic circuit that has produced the result data, but it can also be cells further away from the particular cell, those cells receiving the result data via the local conductors of intervening cells by closing the appropriate switches in the connection circuits between the cells.

The conductors of the cell and switches between the conductors will commonly be referred to as the “routing plane of the cell.

FIG. 2 shows a routing plane of a more complicated cell 20 than the ones shown in FIG. 1, in combination with the connection circuits 220, 222, 224, 226 to the neighboring cells (not shown). The cell 20 contains four local column conductors 24a-d, four local row conductors 26a-d, two global column conductors 25a,b two global row conductors 27a,b and a computation logic circuit 200, 202a,b. Each connection circuit 220, 222, 224, 226 contains four switches 220a-d, 222a-d, 224a-d, 226a-d. Two of the connection circuits 220, 222, 224, 226 are column connection circuits 220, 224, the other two are row connection circuits 222, 226. The switches 220a-d, 224a-d of each column connection circuit are connected on one side to respective ones of the local column conductors 24a-d. On the other side these switches 220a-d, 224a-d are connected to similar column conductors of neighboring cells (not shown) in the column direction. The global column conductors 25a,b run on to the global column conductors of neighboring cells in the column direction without interruption by a switch. The switches 222a-d, 226a-d of each row connection circuit are connected on one side to respective ones of the local row conductors 26a-d. On the other side these switches 222a-d, 226a-d are connected to similar column conductors of neighboring cells (not shown) in the column direction. The global row conductors 27a,b run on to the global row conductors of neighboring cells in the row direction without interruption by a switch.

Within cell 20 column interconnection switches 240a,b are shown connecting pairs of local column conductors 24a-d. Within cell 20 row interconnection switches 260a,b are shown connecting pairs of local row conductors 24a-d. Within cell 20 four cross connection switches 280a-d, each connecting a respective one of the local column conductors 24a-d to a respective one of the local row conductors 26a-d. Within cell 20 two global cross-connection switches 270a,b are shown, each connecting a respective one of the global column conductors 25a,b to a respective one of the global row conductors 27a,b.

The computation logic circuit 200, 202a,b contains a computation core 200 and output connection circuits 202a,b. The computation core 200 has inputs connected to the local column conductors 24a-d, the local row conductors 26a-d, the global column conductors 26a,b and the global row conductors 27a,b. The computation core 200 has outputs connected to the connection circuits 202a,b. The output connection circuits 202a,b have outputs connected to the local row and column conductors of the neighboring cells and to the global row and column conductors 26a,b, 27a,b.

Signals from a configuration memory (not shown) control the function of the computation core 200, the output connection circuits 202a,b and the state of the switches 220a-b, 222a-d, 224a-d, 226a-d in the connection circuits 220, 222, 224, 226, the interconnection switches 240a,b, 260a,b and the cross-connection switches 280a-d, 270a,b.

FIG. 3 shows an embodiment of a computation core 200. The core 200 contains an access network 30, a computation logic block 32 and a distribution circuit 34, coupled in series with one another. One possible embodiment of an access network 30 will be described, but it will be obvious that many alternative embodiments are possible. The access network 30 that is shown contains first and second multiplexers 300a-f, 304a-f interconnected by a connection network 302. The function of first and second multiplexers 300a-f and 304a-f is programmable, using configuration bits stored in a memory (not shown). Each first multiplexer has a pair of inputs coupled to a “horizontal” conductor and a “vertical” conductor respectively. The second multiplexers 304a-f each have four inputs, coupled to the outputs of four of the first multiplexers 300a-f, for example three second multiplexers 300a-c that receive a fist set of outputs of four of first multiplexers 304a-f and three other second multiplexers 300d-f that receive a second set of outputs of four of first multiplexers 300a-f. Here the first and second set both contain the outputs of the first multiplexers 300a-f that are connected to the global conductors 29a,b. Otherwise, they contain the outputs of different ones of the first multiplexers 200a-f that are connected to the local conductors. The outputs of the second multiplexers 304a-f form the outputs of the access network 30. Of course many other kinds of connections between inputs and outputs of access network are possible, for example six 12 to 1 multiplexers.

The outputs of access network 20 are coupled to the inputs of computation logic block 32. One possible embodiment of computation logic block 32 will be described, but it will be obvious that many alternative embodiments are possible. The computation logic block 32 that is shown contains a first and second SRAM 320, 322, an output control multiplexer 324 and a first and second output multiplexer 326, 328. The SRAMs 320, 322 serve as programmable look-up tables that define the relation between input and output. Three inputs of the computation logic block 32 are coupled to an address input of the first SRAM 320, the other three inputs are coupled to an address input of the second SRAM 302. An output of the first SRAM 320 is coupled to a first and second output of the computation logic block 32 via first and second output multiplexer 326, 328 respectively. An output of second SRAM 322 is coupled to the first second output of computation logic block via the first and second output multiplexer 326, 328. The inputs of the computation logic block 32 are coupled to the control inputs of the output control multiplexer 324, which has an output coupled to a control input of the first and second output multiplexer 326, 328, so that either the output of the first SRAM 320 is coupled to the first output of the computation logic block and the output of the second SRAM 322 is coupled to the second output of the computational logic block or vice versa, dependent on the inputs of the computational logic block (the nature of this dependence is controlled by configuration bits (not shown)).

The outputs of computation logic block 32 are coupled to the inputs of distribution circuit 34. Distribution circuit contains a distribution network 340, first and second distribution multiplexer 342a,b, and flip-flops 344a,b. The outputs of the computation logic block 32 are coupled to the inputs of the first distribution multiplexer 342a, directly from the computational logic block 32 and via the first flip-flop 344a. Similarly the outputs of the computation logic block 32 are coupled to the inputs of the second distribution multiplexer 342b, directly from the output of the computational logic block 32 and via the second flip-flop 344b. The outputs of the first and second distribution multiplexer 342a,b form the outputs of the distribution circuit. In operation, the multiplexers are programmed with configuration bits not shown, allowing any output signal of the computation logic block 32 to be passed to any output of the distribution circuit 34, if necessary via a flip-flop to delay the output by one clock cycle, so as to allow pipelined processing.

1. An integrated circuit with programmable logic function, the integrated circuit comprising
a matrix of programmable cells;
programmable switches between pairs of neighboring cells, each cell containing a local conductor connecting a pair of the switches on opposite sides of the cell, each switch connecting the local conductors of the neighboring cells, at least one of the cells comprising a computation logic circuit having either an input connected to the local conductor of the at least one of the cells and programmably individually activatable outputs connected to the local conductors of neighbor cells of the at least one of the cells or an output connected to the local conductor of the at least one of the cells and programmably individually activatable inputs connected to the local conductors of neighbor cells of the at least one of the cells.

2. An integrated circuit according to claim 1, comprising a plurality of programmable switches between each pair of neighboring cells, wherein the at least one of the cells contains a plurality of local conductors, connecting respective pairs of switches on opposite sides of the cell, the computation logic circuit having inputs connected to respective ones of the local conductors of the at least one of the cells.

3. An integrated circuit according to claim 2, the at least one of the cells comprising a programmable interconnection switch connecting different ones of the plurality of conductors.

4. An integrated circuit according to claim 1, comprising a permanently conductive group conductor running through a group of at least two adjacent ones of the cells in the matrix, including the at least one of the cells, the computation logic circuit having programmably individually activatable inputs and outputs connected to the group conductor.

5. An integrated circuit according to claim 1, wherein the matrix contains rows and columns, each cell containing a row conductor and a column conductor connected between a respective pair of the switches on opposite sides of the cell in a row and column direction respectively, the computation logic circuit having inputs connected to the local row and column conductor of the at least one of the cells and programmably individually activatable outputs connected to the local row conductors of neighbor cells of the at least one of the cells in the row direction and to the local column conductors of neighbor cells of the at least one of the cells in the column direction.

6. An integrated circuit according to claim 5, comprising a plurality of programmable switches between each pair of neighboring cells, wherein the at least one of the cells contains a plurality of local row conductors and a plurality of local column conductors, connecting respective pairs of switches on opposite sides of the cell in the row and column direction respectively, the computation logic circuit having inputs connected to respective ones of the local row and column conductors of the at least one of the cells.

7. An integrated circuit according to claim 5, the at least one of the cells comprising a programmable cross connection between the local row and column conductor of the at least one of the cells.
